(19) United States
(12) Patent Application Publication
(10) Pub. No.: US 2026/0305038 A1
(43) Pub. Date: Oct. 1, 2026

(54) DISPLAY DEVICE

(71) Applicant: LG Display Co., Ltd., Seoul (KR)

(72) Inventor: HeonSoo Ha, Gumi-si (KR)

(73) Assignee: LG Display Co., Ltd., Seoul (KR)

(21) Appl. No.: 19/407,233

(22) Filed: Dec. 3, 2025

(30) Foreign Application Priority Data
Mar. 27, 2025 (KR) 10-2025-0039453

(51) Int. Cl. H10H 29/853; H10H 29/856

(52) U.S. Cl. CPC H10H 29/853; H10H 29/856

(57) ABSTRACT

A display device can include a display panel configured to display an image, a cover bottom disposed below the display panel, and a plurality of LED packages disposed above the cover bottom. The LED packages include a plurality of second LED packages disposed at corner portions of the display panel and having a front light emission characteristic, and a plurality of first LED packages disposed in regions other than the corner portions and having a side light emission characteristic, which can effectively improve the luminance uniformity. In addition, there is no need to increase the LED current to compensate for the corner portions and the edge luminance, so it is possible to minimize the increase in power consumption and address heat generation issues.

### CROSS-REFERENCE TO RELATED APPLICATIONS

This application claims priority to the Korean Patent Application No. 10-2025-0039453 filed on Mar 27, 2025, in the Korean Intellectual Property Office, the entire disclosure of which is hereby expressly incorporated by reference into the present application.

### BACKGROUND

### Field

The present disclosure relates to a display device including a backlight unit.

### Discussion of the Related Art

Currently, as our society enters a full-fledged information era, the field of display devices that visually display electrical information signals is rapidly developing, and research has been conducted to improve performances such as thinning, weight reduction, and low power consumption for various display devices.

Various examples of display devices can include a liquid crystal display (LCD), an electro-wetting display (EWD), and an organic light emitting display (OLED).

The display device can include a display panel in which a plurality of sub pixels is disposed, and various driving circuits for driving the plurality of sub pixels. The brightness displayed by each of the plurality of sub pixels is adjusted by various driving circuits, and the display panel can display an image.

The plurality of sub pixels can include light emitting elements to directly emit light. Alternatively, the plurality of sub pixels can receive light from the backlight unit, control the amount of light emitted to the outside of the supplied light, and represent brightness according to image data. In this case, the display device can include a separate light source device that supplies light to the display panel.

Recently, the use of a light emitting diode (LED) combined with characteristics such as small, low power consumption, and high reliability as a light source has been increasing. These LEDs are used for various lighting purposes. In particular, LEDs implementing white light are in the spotlight as backlight units of liquid crystal display devices.

On the other hand, in the direct type backlight unit, the LED is evenly disposed on the screen, but there can be a problem in that the luminance uniformity is lowered due to the low brightness of the screen edge, especially the corner portions, which is far from the LED.

To compensate for this, the currents of the LEDs at the corner and the edge portions are increased, however, this can cause an increase in power consumption and heat generation.

### SUMMARY OF THE DISCLOSURE

An object to be achieved by the present disclosure is to provide a display device in which luminance uniformity is improved by enhancing brightness at the corner and the edge portions.

Another object to be achieved by the present disclosure is to provide a display device which compensates for a luminance without raising an LED current.

Another object to be achieved by the present disclosure is to provide a display device which reduces a thickness of a direct type backlight unit and reduces an LED quantity while improving luminance uniformity.

Objects of the present disclosure are not limited to the above-mentioned objects, and other objects, which are not mentioned above, can be clearly understood by those skilled in the art from the following descriptions.

A display device according to an example embodiment of the present disclosure includes a display panel configured to display an image, a cover bottom disposed below the display panel, and a plurality of LED packages disposed above the cover bottom, wherein the plurality of LED packages includes a plurality of second LED packages disposed at corner portions of the display panel and having a front light emission characteristic, and a plurality of first LED packages disposed in regions other than the corner portions and having a side light emission characteristic.

Other detailed matters of the embodiments of the present disclosure are included in the detailed description and the drawings.

According to aspects of the present disclosure, by applying a distributed Bragg reflector (DBR) LED as a light source of a backlight unit, it is possible to reduce the thickness of a direct type backlight unit and reduce the number of LEDs, thereby reducing manufacturing costs and optimizing a product design.

According to aspects of the present disclosure, in addition to the DBR LED, an LED having a front light emission characteristic is applied to a partial area (particularly, corner portions) as a hybrid structure, thereby effectively improving luminance uniformity. In addition, there is no need to increase the LED current to compensate for the luminance at the corner and the edge portions, so it is possible to minimize the increase in power consumption and heat generation problems.

Further, according to aspects of the present disclosure, the degree of freedom of display design is increased due to the reduced thickness and the reduced LED quantity, so that a thinner and lighter product can be developed, and by applying the hybrid structure, it is possible to design an optimized backlight in various product lines (e.g., TV, monitor, laptop, etc.).

The effects according to the present disclosure are not limited to the contents exemplified above, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a view schematically illustrating a configuration of a display device according to one or more embodiments of the present disclosure.

FIGS. 2A and 2B are views schematically illustrating a cross-sectional structure of a display device according to a first embodiment of the present disclosure.

FIG. 3 is a plan view illustrating a partial configuration of the display device of FIGS. 2A and 2B.

FIG. 4 is a cross-sectional view illustrating a second LED package of FIGS. 2A and 2B.

FIG. 5 is a view illustrating a cross-sectional structure of a second LED chip of FIG. 4.

FIG. 6 is a view illustrating light emission characteristics of the second LED chip of FIG. 4.

FIG. 7 is a cross-sectional view illustrating a first LED package of FIGS. 2A and 2B.

FIG. 8 is a view illustrating a cross-sectional structure of the first LED chip of FIG. 7.

FIG. 9 is a diagram illustrating light emission characteristics of the first LED chip of FIG. 7.

FIG. 10 is a plan view illustrating a part of a configuration of a display device according to a second embodiment of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When an element or layer is disposed “on” another element or layer, another layer or another element can be interposed directly on the other element or therebetween.

Although the terms such as “first”, “second”, and the like are used for describing various components, these components are not confined by these terms. These terms are merely used for distinguishing one component from the other components and may not define order or sequence. Therefore, a first component to be mentioned below can be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated. Further, the term “can” fully encompasses all the meanings and coverages of the term “may” and vice versa.

The features of various embodiments of the present disclosure can be partially or entirely adhered to or combined with each other and can be interlocked and operated in technically various ways, and the embodiments can be carried out independently of or in association with each other.

Hereinafter, various embodiments of the present disclosure will be described in detail with reference to the accompanying drawings. All the components of each display device/apparatus according to all embodiments of the present disclosure are operatively coupled and configured.

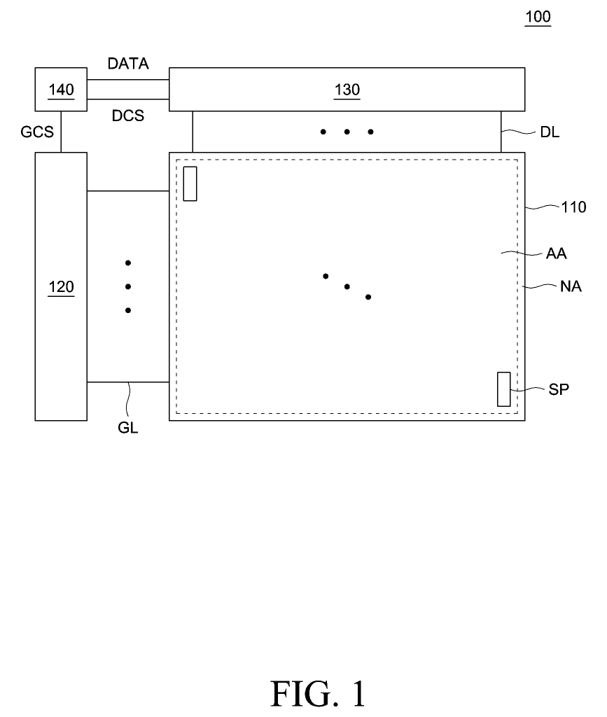

FIG. 1 is a view schematically illustrating a configuration of a display device according to one or more embodiments of the present disclosure.

Referring to FIG. 1, a display device 100 according to example embodiments of the present disclosure can include a display panel 110, a gate driving circuit 120 for driving the display panel 110, a data driving circuit 130, and a controller 140.

The display panel 110 can include an display area AA (or active area) in which a plurality of sub pixels SP are disposed, and a non-display area NA (or non-active area) positioned outside the display area AA.

In the display panel 110, a plurality of gate lines GL and a plurality of data lines DL are disposed, and a sub pixel SP can be positioned in an area where the gate line GL and the data line DL intersect.

Further, the gate driving circuit 120 is controlled by the controller 140 and can sequentially output scan signals to the plurality of gate lines GL disposed in the display panel 110 to control driving timings of the plurality of sub pixels SP.

The gate driving circuit 120 can include one or more gate driver integrated circuits (GDIC) and can be located only on one side or both sides of the display panel 110 depending on a driving method.

Each gate driver integrated circuit can be connected to a bonding pad of the display panel 110 in a tape automated bonding (TAB) manner or a chip on glass (COG) manner. Alternatively, each gate driver integrated circuit is implemented as a gate in panel (GIP) type and can be directly disposed on the display panel 110. Alternatively, each gate driver integrated circuit can be integrated and disposed on the display panel 110. Alternatively, each gate driver integrated circuit can be implemented in a chip on film (COF) manner mounted on a film connected to the display panel 110.

Further, the data driving circuit 130 receives the image data DATA from the controller 140 and converts the image data DATA into an analog data voltage. Further, a data voltage is output to each data line DL in accordance with the timing at which the scan signal is applied through the gate line GL so that each sub pixel SP represents the brightness according to the image data DATA.

The data driving circuit 130 can include one or more source driver integrated circuits (SDICs).

Each source driver integrated circuit can include a shift register, a latch circuit, a digital-to-analog converter, an output buffer, and the like.

Each source driver integrated circuit can be connected to a bonding pad of the display panel 110 using a tape automated bonding (TAB) method or a chip on glass (COG) method. Alternatively, each source driver integrated circuit can be directly disposed on the display panel 110. Alternatively, each source driver integrated circuit can be integrated and disposed on the display panel 110. Alternatively, each source driver integrated circuit can be implemented in a chip on film (COF) manner.

In this case, each source driver integrated circuit can be mounted on a film connected to the display panel 110 and electrically connected to the display panel 110 through lines on the film.

The controller 140 supplies various control signals to the gate driving circuit 120 and the data driving circuit 130 and can control operations of the gate driving circuit 120 and the data driving circuit 130.

The controller 140 can be mounted on a printed circuit board, a flexible printed circuit, or the like, and can be electrically connected to the gate driving circuit 120 and the data driving circuit 130 through a printed circuit board, or a flexible printed circuit.

The controller 140 allows the gate driving circuit 120 to output the scan signal according to the timing set in each frame, and converts the image data received from the outside into a data signal format used by the data driving circuit 130 to output the converted image data DATA to the data driving circuit 130.

The controller 140 receives various timing signals including the vertical synchronization signal, the horizontal synchronization signal, the input data enable signal, and the clock signal from the outside (for example, a host system).

The controller 140 can generate various control signals using various timing signals received from the outside and output the control signals to the gate driving circuit 120 and the data driving circuit 130.

For example, the controller 140 outputs various gate control signals GCS including a gate start pulse, a gate shift clock, and a gate output enable signal. The gate start pulse controls an operation start timing of one or more gate driver integrated circuits constituting the gate driving circuit 120. The gate shift clock is a clock signal commonly input to one or more gate driver integrated circuits and controls the shift timing of the scan signal. The gate output enable signal designates timing information of one or more gate driver integrated circuits.

Further, the controller 140 outputs various data control signals DCS including a source start pulse, a source sampling clock signal, and a source output enable signal to control the data driving circuit 130.

The source start pulse controls the data sampling start timing of one or more source driver integrated circuits constituting the data driving circuit 130. The source sampling clock is a clock signal that controls the sampling timing of data in each of the source driver integrated circuits. The source output enable signal controls the output timing of the data driving circuit 130.

The display device 100 can further include a power management integrated circuit that supplies various voltages or currents to the display panel 110, the gate driving circuit 120, the data driving circuit 130, or controls various voltages or currents to be supplied.

Each sub pixel SP can be an area defined by an intersection between the gate line GL and the data line DL, and at least one circuit element can be disposed therein. Further, depending on the type of the display device 100, a light emitting element or a liquid crystal layer can be disposed in each sub pixel SP.

For example, when the display device 100 is a liquid crystal display device, a liquid crystal layer can be disposed in each sub pixel SP. The display device 100 can include a backlight unit that supplies light to the display panel 110. The backlight unit can include an element for emitting light and various optical elements.

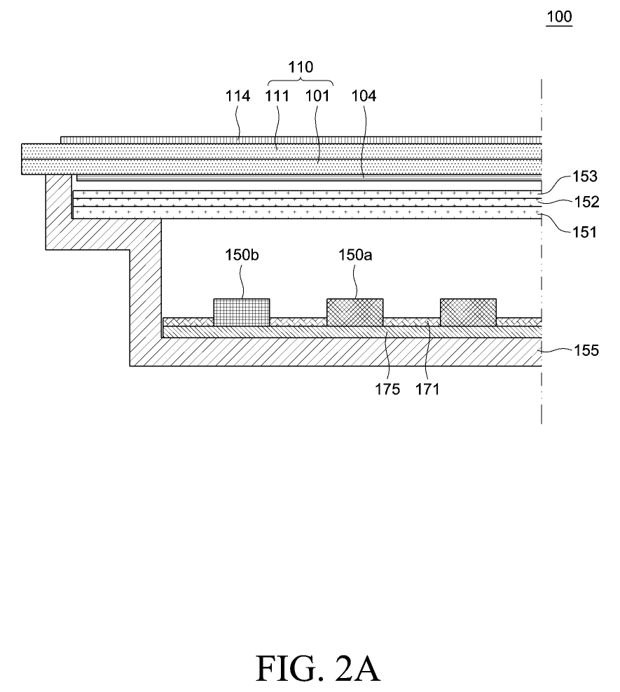

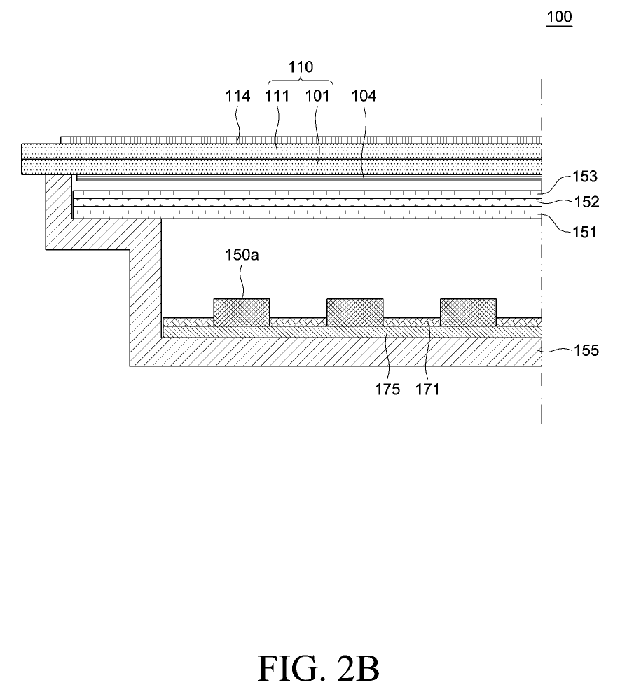

FIGS. 2A and 2B are views schematically illustrating a cross-sectional structure of a display device according to a first embodiment of the present disclosure.

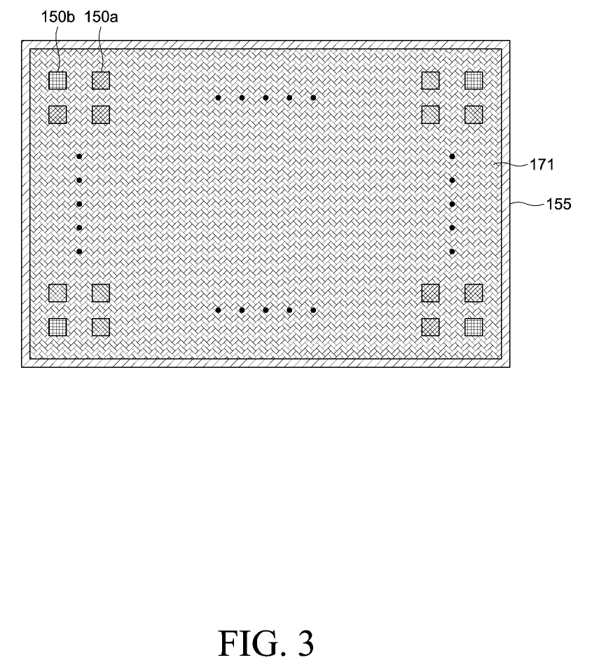

FIG. 3 is a plan view illustrating a partial configuration of the display device of FIGS. 2A and 2B.

For example, FIGS. 2A and 2B illustrate a cross-section of a part of the display device of FIG. 1 taken along a horizontal direction. FIG. 2A illustrates a cross-section of a part of a display device in which an LED package disposed at an uppermost or lowermost end is cut in a horizontal direction based on the LED package of the other area.

FIG. 3 is a plan view of a display device in which an upper optical sheet and a display panel are omitted to confirm the configuration and arrangement of an LED package.

Referring to FIGS. 2A, 2B, and 3, the display device 100 according to the first example embodiment of the present disclosure includes a display panel 110 such as a liquid crystal display panel, and a backlight unit disposed under the display panel 110 to irradiate light to the display panel 110, and can include a cover bottom 155 made of metal or plastic that supports the backlight unit and extends over the entire rear surface of the display panel 110.

The direct type backlight unit can include, for example, an LED substrate 175 disposed on the cover bottom 155 as shown in FIGS. 2A and 2B, a diffusion sheet 151 disposed over the LED substrate 175 to be spaced apart from each other by a predetermined distance to diffuse light from the light source, and a prism sheet 152 and a luminance enhancement film 153 disposed over the diffusion sheet 151. Further, a plurality of diffusion plate supports for preventing the diffusion sheet 151 from sagging can be disposed over the LED substrate 175.

The luminance enhancing film 153 can include a dual brightness enhancement film (DBEF), but is not limited thereto.

The LED substrate 175 can be disposed over the front surface of the display device 100, and LED packages 150a and 150b, which are a plurality of light sources, can be disposed above the LED substrate 175.

Specifically, the display panel 110 can be formed by bonding the first substrate 101 and the second substrate 111 to be spaced apart from each other by a predetermined distance, and a liquid crystal layer interposed therebetween.

Various lines and pixel electrodes as well as thin film transistors can be disposed over the first substrate 101, and a color filter and a black matrix can be disposed over the second substrate 111.

For example, for example, a plurality of gate lines which is arranged vertically and transversely to define a plurality of pixel areas and data lines which are orthogonal to the plurality of pixel areas can be disposed over the first substrate 101 and a thin film transistor which is a switching element can be disposed in each of the pixel areas. In this case, the thin film transistor can include a gate electrode connected to the gate line, a semiconductor layer formed of amorphous silicon or the like over an upper portion of the gate electrode, and a source electrode and a drain electrode disposed over the semiconductor layer and electrically connected to the data line and the pixel electrode.

Further, the second substrate 111 can include a color filter composed of a plurality of sub-color filters that implement red, green, and blue colors, and a black matrix that separates the sub-color filters and blocks light passing through the liquid crystal layer.

The first substrate 101 and the second substrate 111 configured as described above are bonded to be opposite to each other by a sealant disposed at an outer periphery of the display area to constitute the display panel 110. The first polarizer 104 and the second polarizer 114 are attached to outer sides of the first substrate 101 and the second substrate 111, respectively, to polarize light incident on the display panel 110 to implement an image.

Further, the backlight unit can include a plurality of LED packages 150a and 150b which is disposed below the display panel 110 to emit light, an LED substrate 175 to which the LED packages 150a and 150b are bonded, and a reflection plate 171 which is disposed on an upper surface of the LED substrate 175 to reflect the backlight light.

Here, as the LED packages 150a and 150b, a method of emitting monochromatic light of red, green, and blue, respectively, or a method of emitting white light by one package can be used.

When LED packages that emit monochromatic light are disposed, red, green, and blue monochromatic LED packages can be alternately disposed at regular intervals, such that monochromatic light emitted therefrom can be mixed as white light and then supplied to the display panel 110. Further, when LED packages that emit white light are provided, a plurality of LED packages can be disposed at regular intervals to supply white light to the display panel 110.

In addition, in the method in which one package emits white light, if the LED element, which is a light source, is a red light emitting element that emits red light, a green-blue fluorescent layer made of a green fluorescent material and a blue fluorescent material is further included inside the lead frame, and when the LED element is a green light emitting element that emits green light, a red-blue fluorescent layer made of a red fluorescent material and a blue fluorescent material can be further included inside the lead frame. Further, in the case of a blue light emitting device emitting blue light, a red-green fluorescent layer made of a red fluorescent material and a green fluorescent material can be further included inside the lead frame.

Further, a plurality of optical sheets 151, 152, and 153 can be disposed over the plurality of LED packages 150a and 150b to be spaced apart from each other by a predetermined distance.

The optical sheets 151, 152, and 153 perform a function of improving the efficiency of light emitted from the LED packages 150a and 150b and supplying the light to the display panel 110. The optical sheets 151, 152, and 153 can include a diffusion sheet 151 for diffusing light emitted from the LED packages 150a and 150b, and a plurality of prism sheets 152 for condensing light diffused by the diffusion sheet 151 to supply uniform light to the display panel 110. Further, the optical sheets 151, 152, and 153 can further include a luminance enhancing film 153 such as a dual brightness enhancement film (DBEF) on the prism sheet 152.

The LED substrate 175, the LED packages 150a and 150b, and the optical sheets 151, 152, and 153 of the backlight unit having such a structure can be accommodated in the cover bottom 155.

For example, the cover bottom 155 includes a lower portion positioned below the LED substrate 175 and a side portion extending in a vertical direction from an edge of the lower portion, and can accommodate the LED substrate 175, the LED packages 150a and 150b, and the optical sheets 151, 152, and 153.

The side portion of the cover bottom 155 can be doubly bent so that the optical sheets 151, 152, 153 and the edges of the display panel 110 are seated and supported, but is not limited thereto.

On the other hand, the edge type backlight unit has an advantage that it is possible to be slim because only a space equal to the thickness of the light guide plate is required, but it is difficult to implement a high luminance because light is provided only from the side, a manufacturing cost is high due to components such as the light guide plate, and it is difficult to implement a local dimming function that irradiates light only in a local area of the display device.

The direct type backlight unit of the present disclosure has advantages in that the light is directly irradiated to the display panel 110 from a plurality of light sources disposed on the rear surface of the display device 100, so that high luminance is possible, the manufacturing cost is low, and the local dimming is easily implemented. However, there is a disadvantage in that the optical gap, which is the gap between the light source and the diffusion sheet 151, must be constant or larger so that the light from the LED packages 150a and 150b, which are a plurality of point light sources, can be sufficiently diffused to the display panel 110, so that the light from the LED packages 150a and 150b, which are the plurality of point light sources, has a limitation in slimming due to the relatively large thickness.

The present disclosure is characterized in that the DBR (Distributed Bragg Reflector) LED is applied as the light source of the backlight unit, thereby reducing the thickness of the direct type backlight unit and reducing the number of LEDs, thereby reducing manufacturing costs and optimizing the product design. For example, the DBR LED can effectively reflect and amplify light of a specific wavelength through the Bragg reflection structure, thereby improving light efficiency. Therefore, it is possible to provide a higher light output than a normal LED, thereby reducing the number of LEDs required to implement the same brightness. As a result, there is an effect of reducing power consumption and reducing heat generation, and the burden of heat management is reduced, so the design can be optimized. In addition, a conventional direct type backlight unit requires a constant height (thickness) to diffuse the LED light source, but the DBR LED maximizes the light-emitting efficiency through the reflective structure to secure a sufficient amount of light even in a thinner space. Accordingly, the LED arrangement density can be lowered, and the overall thickness of the backlight unit can be reduced.

Further, in addition to the DBR LED, the present disclosure is characterized in that the luminance uniformity can be effectively improved by applying an LED having a front light emission characteristic to a partial area (particularly, corner portions) as a hybrid structure. In addition, there is no need to increase the LED current to compensate for the corner and edge luminance, so it is possible to minimize the increase in power consumption and heat generation problems.

For example, in the present disclosure, in order to solve the problem in the conventional direct type backlight unit, a Distributed Bragg Reflector (DBR) LED capable of reducing the thickness of the product and reducing the number of LEDs was applied, but there still remained the problem of lowering the luminance of the outer and corner portions. The conventional direct type backlight unit disposes a plurality of LEDs at uniform intervals under a display panel, but there is a problem in that the brightness of screen edges, particularly at the corners distant from the LEDs, is reduced. To compensate for this, when the LED drive current in the corresponding area is increased, the luminance uniformity is improved, but this causes an increase in power consumption and a heat generation problem.

To improve this, the present disclosure is characterized in that a hybrid structure is applied, in which DBR LEDs are disposed in the center and general LEDs having a front light emission characteristic are applied to the corner and the outer portions.

This method effectively compensates for the luminance of the corner portions and does not require an LED current increase, thereby effectively reducing power consumption and heat generation. As a result, it is possible to improve luminance uniformity while maintaining the effect of reducing the thickness of the direct type backlight unit and reducing the LED quantity, and to solve the problem of power consumption and heat generation.

To this end, the plurality of LED packages 150a and 150b of the present disclosure can include a plurality of first LED packages 150a disposed in the entire area excluding the corner portions of the display device 100 and a plurality of second LED packages 150b disposed in the corner portions. However, the present disclosure is not limited thereto, and the plurality of second LED packages 150b can be disposed at four corners including corner portions. In addition, as another example, when higher brightness is required in a specific direction (e.g., the lower end of the screen), the second LED package 150b can be additionally disposed in addition to the first LED package 150a only at the lower edge or in a specific area.

In this case, the first LED package 150a can be configured by a DBR LED having a side emission characteristic, and the second LED package 150b can be configured by a general LED having a front emission characteristic.

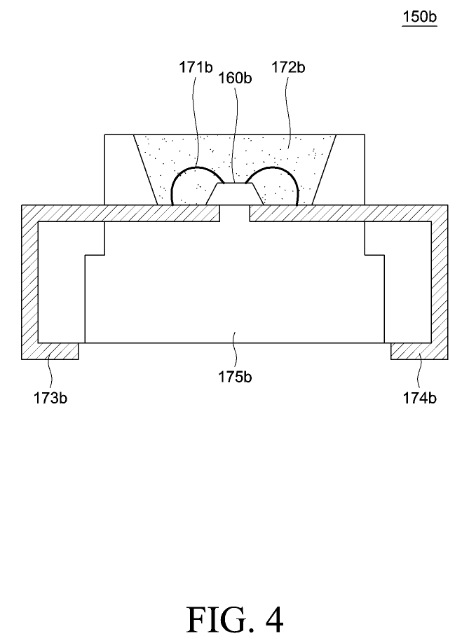

The first LED package 150a and the second LED package 150b will be described in detail with reference to FIGS. 4 to 9.

FIG. 4 is a cross-sectional view illustrating a second LED package of FIGS. 2A and 2B.

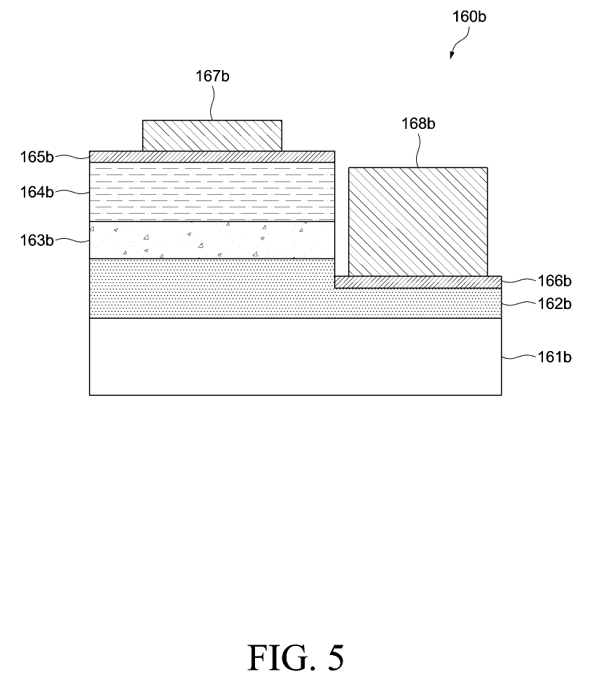

FIG. 5 is a view illustrating a cross-sectional structure of a second LED chip of FIG. 4.

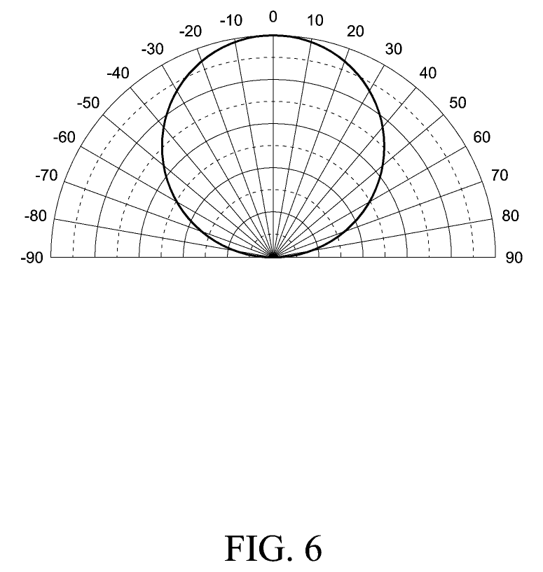

FIG. 6 is a view illustrating light emission characteristics of the second LED chip of FIG. 4.

Referring to FIG. 4, the second LED package 150b according to the first embodiment of the present disclosure can be configured by a general LED having a front light emission characteristic.

The second LED package 150b of the present disclosure can be disposed at corner portions of the display device 100. For example, when the shape of the display device 100 is a rectangle, the second LED package 150b can be disposed at four corners of the rectangle, but is not limited thereto. When the shape of the display device is a polygon such as a pentagon or a hexagon, the second LED package 150b can be disposed at a vertex.

The second LED package 150b can include a second LED chip 160b and a second phosphor 172b that emit light.

Further, according to another embodiment of the present disclosure, the second LED package 150b can further include a second lens which covers the second LED chip 160b and the second phosphor 172b.

The second LED chip 160b can be seated on the second heat dissipation slug 175b, and the second heat dissipation slug 175b is surrounded by a case serving as a housing, and the second phosphor 172b is filled therein.

The case can be provided with a pair of 2-1 and 2-2lead frames 173b and 174b electrically connected to each other through the second LED chip 160b and a wire 171b to be exposed to the outside of the case.

The second lens can be disposed above the case. The second lens can cover and protect the reflective surface of the second heat dissipation slug 175b, including the second LED chip 160b and the second phosphor 172b, and the wire 171b, and can control the angle of the main emission light generated from the second LED chip 160b.

The 2-1 and 2-2 lead frames 173b and 174b can be provided outside and electrically connected to a current-supply source which supplies an operating current for emitting light of the second LED chip 160b.

When a current is applied to the second LED chip 160b, light is emitted, and the emitted light is mixed with the light emitted by the second phosphor 172b to emit white light to the outside.

The second LED package 150b requires a pair of wires 171b for the second LED chip 160b to receive an operating current from the current-supply source.

Meanwhile, referring to FIG. 5, the second LED chip 160b according to the first embodiment of the present disclosure can be configured by forward bonding of the second p-type semiconductor layer 164b that provides holes and the second n-type semiconductor layer 162b that provides electrons as a portion that substantially emits light.

Looking at the second LED chip 160b in more detail, the second n-type semiconductor layer 162b, the second active layer 163b, the second p-type semiconductor layer 164b, the second reflection plates 165b and 166b, the second n-type electrode 168b, and the second p-type electrode 167b, which are sequentially stacked on the substrate 161b, can be included.

The substrate 161b can be preferably formed using a transparent material including sapphire, but is not limited thereto.

Here, a buffer layer for improving lattice matching between the substrate 161b and the second n-type semiconductor layer 162b can be disposed, and the buffer layer can be formed of GaN or AlN/GaN or the like.

In this case, the second n-type semiconductor layer 162b can be formed of GaN doped with an n-type conductivity type impurity or GaN/AlGaN, and Si, Ge, Sn, or the like can be used as the n-type conductivity type impurity.

Further, the second p-type semiconductor layer 164b can be formed of GaN or GaN/AlGaN doped with p-type conductivity-type impurities, and Mg, Zn, Be, or the like can be used as the p-type conductivity-type impurities.

In the second LED chip 160b, a part of the second p-type semiconductor layer 164b and a part of the second active layer 163b are removed by mesa etching so that a part of the second n-type semiconductor layer 162b is exposed, and the second p-type semiconductor layer 164b and the second active layer 163b can be formed on a part of the second n-type semiconductor layer 162b.

Accordingly, the second n-type electrode 168b is configured at one corner of the exposed second n-type semiconductor layer 162b, and the second p-type electrode 167b forms a horizontal second LED chip 160b on which the electrode is disposed by a top-to-top method, which is configured on the second p-type semiconductor layer 164b.

The second active layer 163b can be a GaN-based single quantum well (SQW) or a multi-quantum well (MQW) and can be formed of a quantum structure such as a superlattice (SL).

The quantum structure of the second active layer 163b can be formed by combining various GaN-based materials, and for example, AlGaN, AlNGaN, InGaN, or the like can be used.

When an electric field is applied to the second active layer 163b, light is generated by the coupling of the electron-hole pair. Accordingly, in the second LED chip 160b, when a voltage is applied between the second P-type electrode 167b and the second n-type electrode 168b, holes and electrons are injected through the second P-type electrode 167b and the second n-type electrode 168b, respectively, and as holes and electrons recombine in the second active layer 163b, excess energy is converted into light and discharged to the outside through the substrate 161b.

The second LED chip 160b of the present disclosure further includes 2-1 and 2-2 reflection plates 165b and 166b for improving the luminous efficiency of light emitted from the second LED chip 160b, for example, the 2-1 and 2-2 reflection plates 165b and 166b are provided to reflect light emitted from the second LED chip 160b to the front surface.

For example, the 2-1 reflection plate 165b is formed on the second p-type semiconductor layer 164b, and the 2-2 reflection plate 166b is positioned between the second n-type electrode 168b and the second n-type semiconductor layer 162b, and is positioned between the second p-type electrode 167b and the second p-type semiconductor layer 164b to serve as an electrical contact part for distributing current, while serving as a mirror for reflecting light generated in the second active layer 163b in a direction toward the second n-type electrode 168b and the second p-type electrode 167b.

The 2-1 and 2-2 reflection plates 165b and 166b are preferably formed of a metal material having a reflectivity of 70% or more in a visible ray region of Ag, Al, Mo, Cr, and a wavelength in the vicinity of an ultraviolet ray portion and an infrared ray in order to increase a reflectivity.

It can be seen that the second LED package 150b of the present disclosure configured as described above has a front light emission characteristic as illustrated in FIG. 6, and thus can be disposed at corner portions of the display device 100. For example, by disposing the second LED package 150b of the present disclosure having a front light emission characteristic at screen edges, particularly at corner portions, which is far from the light source, it is possible to compensate for the luminance of the corner portions, thereby effectively improving the luminance uniformity.

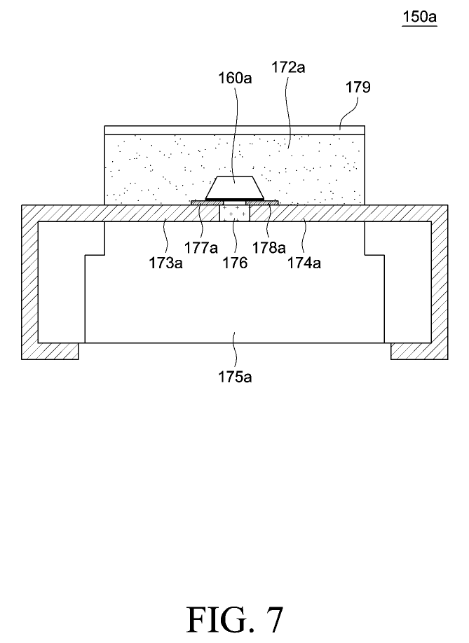

FIG. 7 is a cross-sectional view illustrating a first LED package of FIGS. 2A and 2B.

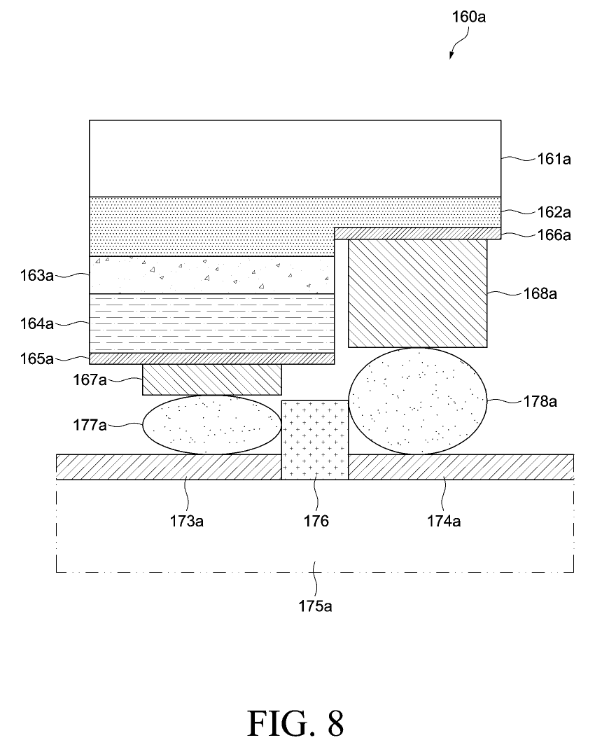

FIG. 8 is a view illustrating a cross-sectional structure of the first LED chip of FIG. 7.

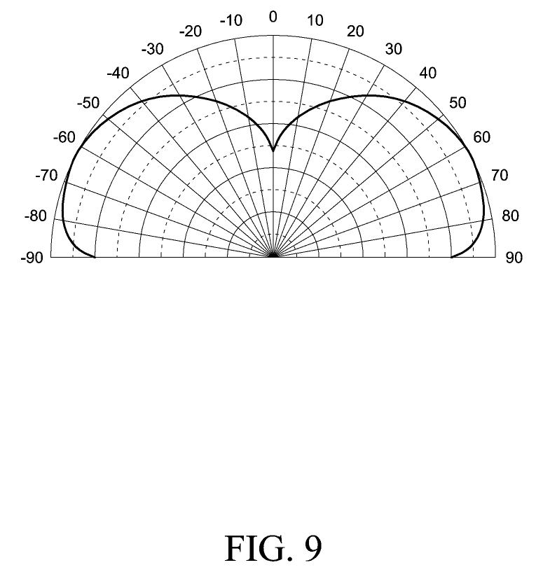

FIG. 9 is a diagram illustrating light emission characteristics of the first LED chip of FIG. 7.

Referring to FIGS. 7 and 8, the first LED package 150a can include a first LED chip 160a that emits light.

Further, according to another embodiment of the present disclosure, the first LED package 150a can further include a first lens which covers the first LED chip 160a.

The first LED package 150a can include a pair of 1-1 and 1-2 lead frames 173a and 174a, a first heat dissipation slug 175a configured to receive a portion of the 1-1 and 1-2 lead frames 173a and 174a at an inner side thereof, and a first LED chip 160a mounted on the 1-1 and 1-2 lead frames 173a and 174a positioned inside the first heat dissipation slug 175a.

In the first LED chip 160a, the first p-type electrode 167a and the first n-type electrode 168a are electrically connected to the 1-1 and 1-2 lead frames 173a and 174a on the first heat dissipation slug 175a, respectively, to emit light by receiving power.

In addition, the first heat dissipation slug 175a is a part that conducts and discharges high-temperature heat accompanying the emission of the first LED chip 160a to the outside, and is made of metal, and the first heat dissipation slug 175a is surrounded by a case serving as a housing and is filled with the first phosphor 172a therein.

In this case, a current-supply source for supplying a power source (+) and a ground power source (-) for emitting light of the first LED chip 160a is provided on the outside, and the 1-1 and 1-2 lead frames 173a and 174a are exposed to the outside of the case to be electrically connected to the current-supply source.

The first lens can be disposed above the case.

The first lens can cover and protect the reflective surface of the first heat dissipation slug 175a including the first LED chip 160a and the first phosphor 172a and control the angle of the main emission light generated from the first LED chip 160a.

The first lens can control an emission angle of light generated from each of the first LED chips 160a.

When the power (+) and the ground power (-) are supplied to the first LED chip 160a through the 1-1 and 1-2 lead frames 173a and 174a, the first LED chip 160a emits light. Further, a part of the light emitted from the first LED chip 160a excites the first phosphor 172a on the inner wall of the first lens, and the light emitted from the first phosphor 172a is mixed with the remaining light to emit white light outward.

In the case of the first LED package 150a, a diffusion layer 179 can be further disposed on the first phosphor 172a, and a first lens can be disposed on the diffusion layer 179.

The diffusion layer 179 serves as a layer for Bragg reflection, and is configured as a single layer, and can be made of, for example, silicon and silicon dioxide (SiO₂).

Looking at the first LED chip 160a in more detail, the first n-type semiconductor layer 162a, the first active layer 163a, the first p-type semiconductor layer 164a, the first reflection plates 165a and 166a, the first n-type electrode 168a, and the first p-type electrode 167a which are sequentially stacked on the substrate 161a can be included. Here, the first LED chip 160a has a flip-chip shape which is turned upside down with respect to the second LED chip 160b. Therefore, structures from the first n-type semiconductor layer 162a to the first n-type electrode 168a and the first p-type electrode 167a can be sequentially stacked in the downward direction of the substrate 161a.

The substrate 161a can be preferably formed using a transparent material including sapphire, but is not limited thereto.

Here, a buffer layer for improving lattice matching between the substrate 161a and the first n-type semiconductor layer 162a can be disposed, and the buffer layer can be formed of GaN or AlN/GaN or the like.

In this case, the first n-type semiconductor layer 162a can be formed of GaN doped with an n-type conductivity type impurity or GaN/AlGaN, and Si, Ge, Sn, or the like can be used as the n-type conductivity type impurity.

Further, the first p-type semiconductor layer 164a can be formed of GaN doped with p-type conductivity-type impurities or GaN/AlGaN, and Mg, Zn, Be, or the like can be used as the p-type conductivity-type impurities.

In the first LED chip 160a, a part of the first p-type semiconductor layer 164a and a part of the first active layer 163a are removed by mesa etching so that a part of the first n-type semiconductor layer 162a is exposed, and the first p-type semiconductor layer 164a and the first active layer 163a can be formed on a part of the first n-type semiconductor layer 162a.

Accordingly, the first n-type electrode 168a can be configured at one corner of the exposed first n-type semiconductor layer 162a, and the first p-type electrode 167a can be configured on the first p-type semiconductor layer 164a.

The first active layer 163a can be a GaN-based single quantum well (SQW) or a multi-quantum well (MQW) and can be formed of a quantum structure such as a superlattice (SL).

The quantum structure of the first active layer 163a can be formed by combining various GaN-based materials, and for example, AlGaN, AlNGaN, InGaN, or the like can be used.

When an electric field is applied to the first active layer 163a, light is generated by the coupling of the electron-hole pair. Accordingly, in the first LED chip 160a, when a voltage is applied between the first P-type electrode 167a and the first n-type electrode 168a, holes and electrons are injected through the first P-type electrode 167a and the first n-type electrode 168a, respectively, and as holes and electrons recombine in the first active layer 163a, excess energy is converted into light and discharged to the outside through the substrate 161a.

The first LED chip 160a of the present disclosure can further include 1-1 and 1-2 reflection plates 165a and 166a for improving luminous efficiency of light emitted from the first LED chip 160a.

For example, the 1-1 reflection plate 165a is formed on the first p-type semiconductor layer 164a, and the 1-2 reflection plate 166a is positioned between the first n-type electrode 168a and the first n-type semiconductor layer 162a, and is positioned between the first p-type electrode 167a and the first p-type semiconductor layer 164a, thereby acting as an electrical contact part for distributing current, while acting as a mirror for reflecting light generated in the first active layer 163a in a direction toward the first n-type electrode 168a and the first p-type electrode 167a.

The 1-1 and 1-2 reflection plates 165a and 166a are preferably formed of a metal material having a reflectivity of 70% or more in a visible ray region of Ag, Al, Mo, Cr, etc. and a wavelength in the vicinity of an ultraviolet ray portion and an infrared ray to increase the reflectivity.

Meanwhile, as illustrated in FIG. 7, the first LED package 150a of the present disclosure is characterized in that the 1-1 and 1-2 lead frames 173a and 174a and the first LED chip 160a electrically connect to each other through eutectic bonding. Eutectic bonding is a bonding method by thermal compression at a high temperature of 200-700°C or higher, and is one of the very robust and highly reliable bonding processes.

The 1-1 and 1-2 lead frames 173a and 174a to be eutectically bonded with the first LED chip 160a of the present disclosure can be formed by a material selected from the group consisting of Au/Sn, Au/Ni, Au/Ge, Au, Sn or Ni, or plating thereof.

Each of the first n-type electrodes 168a and the first p-type electrodes 167a of the first LED chip 160a to be eutectically bonded to the 1-1 and 1-2 lead frames 173a and 174a can be formed of a material selected from a group consisting of Au/Sn, Au/Ni, Au/Ge, Au, Sn or Ni, or plating thereof.

In an embodiment of the present disclosure, the first n-type electrode 168a and the first p-type electrode 167a of the first LED chip 160a can be formed as Au/Sn, and the 1-1 and 1-2 lead frames 173a and 174a can be formed as Au. When heat and pressure are applied while the first p-type electrode 167a and the first n-type electrode 168a formed by Au/Sn are in contact with the 1-1 and 1-2 lead frames 173a and 174a formed by Au, respectively, the contact portions of the 1-1 and 1-2 lead frames 173a and 174a in contact with the first p-type electrode 167a and the first n-type electrode 168a are melted to form a eutectic mixture of Au-Sn from the interfaces of the first p-type electrode 167a and the first n-type electrode 168a and the 1-1, 1-2 lead frames 173a and 174a, respectively. The eutectic alloy has a constant Au:Sn composition ratio and serves as conductive adhesives 177a and 178a. The first LED chip 160a can be strongly attached onto the 1-1 and 1-2 lead frames 173a and 174a by conductive adhesives 177a and 178a made of an eutectic alloy.

This eutectic bonding method not only realizes high bonding strength, but also has the advantage that it is not necessary to apply a separate adhesive from the outside.

In another embodiment of the present disclosure, the first n-type electrode 168a and the first p-type electrode 167a of the first LED chip 160a can be formed as Au, and the 1-1 and 1-2 lead frames 173a and 174a can be formed as Au/Sn.

In this way, the first p-type electrode 167a and the first n-type electrode 168a of the first LED chip 160a are eutectically bonded to the 1-1 and 1-2 lead frames 173a and 174a, and the first LED chip 160a can be flip-chip bonded onto the 1-1 and 1-2 lead frames 173a and 174a.

Accordingly, in the process of receiving power from an external current-supply source, the first LED package 150a according to the first embodiment of the present disclosure can receive power through the 1-1 and 1-2 lead frames 173a and 174a without a separate connection line such as a wire.

An insulating layer 176 can be further provided between the first p-type electrode 167a and the first n-type electrode 168a of the first LED chip 160a or between the first and second lead frames 173a and 174a or between the first p-type electrode 167a and the first n-type electrode 168a of the first LED chip 160a or between the 1-1, 1-2 lead frames 173a and 174a of the first LED chip 160a.

For example, the insulating layer 176 can be any one or a combination of two or more selected from the group including SiO₂, Si₃N₄, Al₂O₃, TiO₂, HfO₂, T₂O₃, MgO, and AlN.

It can be seen that the first LED package 150a of the present disclosure configured as described above has a side light emission characteristic as illustrated in FIG. 9, and thus can be disposed in the entire area excluding the corner portions of the display device 100.

According to the present disclosure, in addition to the first LED package 150a having a side light emission characteristic, the second LED package 150b having a front light emission characteristic is applied to a partial area (particularly, corner portions) in a hybrid structure to effectively improve the luminance uniformity. In addition, there is no need to increase the LED current to compensate for the corner and the edge luminance, so it is possible to minimize the increase in power consumption and heat generation problems.

In the comparative example in which the LED package having the side light emission characteristics is disposed in the entire area, it can be seen that the uniformity is 100% and the light flux (power consumption) of the corner LED package is 100% as the LED package is disposed evenly.

On the other hand, in the embodiment in which the first LED package having the side light emission characteristic is disposed in the center portion and the second LED package having the front light emission characteristic is applied to the corner portions in a hybrid structure, it can be seen that the uniformity is improved to 130% as the second LED package having the front light emission characteristic is disposed in the corner portions, and the luminous flux (consumption power) of the second LED package in the corner portions is reduced to 75%.

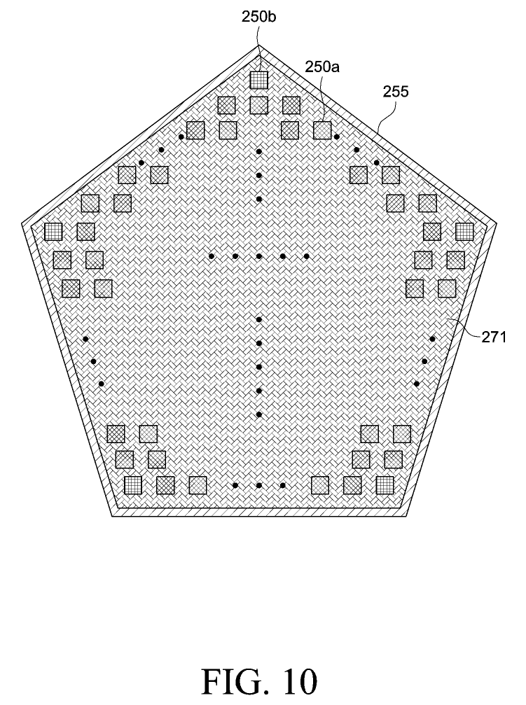

Meanwhile, in the case where the shape of the display device is a polygonal shape, such as a pentagon or a hexagon, the second LED package can be disposed at a vertex, which will be described in detail with reference to FIG. 10.

FIG. 10 is a plan view illustrating a part of a configuration of a display device according to a second embodiment of the present disclosure.

One difference (or the only difference) between the second embodiment of the present disclosure of FIG. 10 and the first embodiment of FIGS. 1 to 9 described above is that the shape of the display device is a pentagon, and other configurations are substantially the same, so that a redundant description will be omitted or may be briefly provided. The same components will be denoted by the same reference numerals. Descriptions of the same reference numerals can refer to FIG. 1 through FIG. 9.

For reference, FIG. 10 is a plan view of a display device in which an upper optical sheet and a display panel are omitted to confirm the configuration and arrangement of the LED package.

Referring to FIG. 10, the display device according to the second example embodiment of the present disclosure can include a display panel, a backlight unit disposed under the display panel to emit light, and a cover bottom 255 extending over the entire rear surface of the display panel.

Further, in the case of a direct type backlight unit, an LED substrate, a reflection plate 271, and optical sheets such as a diffusion sheet, a prism sheet, and a luminance enhancement film are included to help uniform distribution of the backlight light.

The backlight unit of the present disclosure is characterized by reducing the quantity of LEDs and reducing the power consumption by applying the DBR LED to solve the thickness problem of the existing direct type backlight unit. Since the DBR LED effectively reflects and amplifies light of a specific wavelength to improve light efficiency, the number of LEDs n to implement the same brightness can be reduced. Accordingly, a sufficient amount of light can be secured while reducing the thickness of the direct backlight unit.

Further, the backlight unit of the second example embodiment of the present disclosure is characterized in that a hybrid structure in which a first LED package 250a made of DBR LEDs is disposed in the center, and a second LED package 250b made of general LEDs having front light emission characteristics is added to the corner portions and edges. Accordingly, it is possible to effectively reduce power consumption and heat generation without increasing the LED current while compensating for the luminance of the corner portions and the edges.

In particular, in the second example embodiment of the present disclosure, when the display device has a polygonal shape, such as a pentagon or a hexagon, the second LED package 250b can be disposed at a vertex to maintain luminance uniformity. This allows uniform brightness to be provided at the edges or corners of the screen. However, the present disclosure is not limited thereto, and the plurality of second LED packages 250b can be disposed at five corners including the vertex.

The example embodiments of the present disclosure can also be described as follows:

A display device according to an example embodiment of the present disclosure includes a display panel configured to display an image, a cover bottom disposed below the display panel, and a plurality of LED packages disposed above the cover bottom, wherein the plurality of LED packages can include a plurality of second LED packages disposed at corner portions of the display panel and having a front light emission characteristic, and a plurality of first LED packages disposed in regions other than the corner portions and having a side light emission characteristic.

The plurality of second LED packages can be disposed at all four corners, including the corner portions.

When the shape of the display panel is polygonal, the plurality of second LED packages can be disposed at vertices of the polygon.

The first LED package can include a first LED chip emitting light, a first phosphor disposed on the first LED chip, and a first lens covering a diffusion layer disposed on the first phosphor, and the second LED package can include a second LED chip emitting light and a second phosphor disposed on the second LED chip.

The diffusion layer can be configured as a single layer made of silicon (silicon) and silicon dioxide (SiO₂).

The second LED package can further include a pair of wires for the second LED chip to receive an operating current from a current-supply source, and the first LED package may not include any wires.

The first LED chip can include a first n-type semiconductor layer, a first active layer, a first p-type semiconductor layer, a first reflection plate, a first n-type electrode, and a first p-type electrode sequentially stacked in a first direction on the first substrate, and the second LED chip can include a second n-type semiconductor layer, a second active layer, a second p-type semiconductor layer, a second reflection plate, a second n-type electrode, and a second p-type electrode sequentially stacked in a second direction on the second substrate.

The second direction can be opposite to the first direction.

The first LED package can be a distributed Bragg reflector (DBR) LED.

The first LED package can further include 1-1 and 1-2 lead frames electrically connected to the current-supply source, and each of the 1-1 lead frame and the 1-2 lead frame can be electrically connected to each other through eutectic bonding with the first p-type electrode and the first n-type electrode.

Although the example embodiments of the present disclosure have been described in detail with reference to the accompanying drawings, the present disclosure is not limited thereto and can be embodied in various forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a display panel configured to display an image;
a cover bottom disposed below the display panel; and
a plurality of light emitting diode (LED) packages disposed above the cover bottom,
wherein the plurality of LED packages include:
a plurality of second LED packages disposed at corner portions of the display panel and having a front light emission characteristic, and
a plurality of first LED packages disposed in regions other than the corner portions of the display panel and having a side light emission characteristic.

2. The display device according to claim 1, wherein the plurality of second LED packages are disposed at all corners, including the corner portions, of the display panel.

3. The display device according to claim 1, wherein, when the display panel has a shape of a polygon, the plurality of second LED packages are disposed at or near vertices of the polygon.

4. The display device according to claim 1, wherein one of the plurality of first LED packages includes:
a first LED chip configured to emit light;
a first phosphor disposed over the first LED chip; and
a diffusion layer disposed over the first phosphor.

5. The display device according to claim 4, wherein one of the plurality of second LED packages includes:
a second LED chip configured to emit light; and
a second phosphor disposed over the second LED chip.

6. The display device according to claim 4, wherein the diffusion layer is configured as a single layer including silicon and silicon dioxide (SiO₂).

7. The display device according to claim 5, wherein the one of the plurality of second LED packages further includes a pair of wires for receiving an operating current from a current-supply source.

8. The display device according to claim 7, wherein the one of the plurality of first LED packages excludes wires.

9. The display device according to claim 5, wherein the first LED chip includes a first n-type semiconductor layer, a first active layer, a first p-type semiconductor layer, a first reflection plate, a first n-type electrode, and a first p-type electrode sequentially stacked in a first direction over a first substrate.

10. The display device according to claim 9, wherein the second LED chip includes a second n-type semiconductor layer, a second active layer, a second p-type semiconductor layer, a second reflection plate, a second n-type electrode, and a second p-type electrode sequentially stacked in a second direction over the second substrate.

11. The display device according to claim 10, wherein the second direction is opposite to the first direction.

12. The display device according to claim 4, wherein the one of the plurality of first LED packages is a distributed Bragg reflector (DBR) LED.

13. The display device according to claim 7, wherein the first LED package further includes a 1-1 lead frame and a 1-2 lead frame electrically connected to the current-supply source.

14. The display device according to claim 13, wherein the 1-1 lead frame and the 1-2 lead frame are electrically connected to each other through a first p-type electrode and a first n-type electrode of the first LED chip.

15. The display device according to claim 14, wherein the 1-1 lead frame and the 1-2 lead frame are electrically connected to each other through the first p-type electrode and the first n-type electrode through eutectic bonding.

16. The display device according to claim 14, wherein the 1-1 lead frame and the 1-2 lead frame are electrically connected to each other through the first p-type electrode and the first n-type electrode, by a thermal compression at a high temperature of 200-700°C or higher.

17. The display device according to claim 5, wherein the first LED chip has a flip-chip shape which is turned upside down with respect to the second LED chip.
